(19) United States
(12) Patent Application Publication
(10) Pub. No.: US 2025/0319563 A1
(43) Pub. Date: Oct. 16, 2025

(54) DUAL ZONE PEDESTAL COOLANT DISTRIBUTION SYSTEM

(71) Applicant: Applied Materials, Inc., Santa Clara, CA (US)

(72) Inventors: Liurui LI, Santa Clara, CA (US); Borui XIA, Santa Clara, CA (US); Kuttappa MUTHANNA, Karnataka (IN); Bharath Bopanna PUTTICHANDA, Santa Clara, CA (US)

(21) Appl. No.: 18/637,079

(22) Filed: Apr. 16, 2024

(51) Int. Cl. B23Q 11/10; B23Q 3/10

(52) U.S. Cl. CPC B23Q 11/10; B23Q 3/10

(57) ABSTRACT

Embodiments of the present invention generally relate to fluid circuit for the use in a pre-cleaning chamber. In one embodiment, a fluid circuit for a substrate support assembly includes a substrate support. The substrate support includes an inner zone and an outer zone. The inner zone includes one or more inner channels and the outer zone includes one or more outer channels. The fluid circuit further includes, a first cooling channel fluidly coupled to the inner zone and a second cooling channel fluidly coupled to the outer zone. The fluid circuit further includes, a heater and one or more valves operable to switch between a first state and a second state. In the first state, the one or more valves fluidly couple the first cooling channel to the heater. In the second state, the one or more valves fluidly couple the second cooling channel to the heater.

### BACKGROUND

### Field

Embodiments of the present invention generally relate to fluid circuit for the use in a pre-cleaning chamber, and more specifically, a fluid circuit used for controlling the temperature of a substrate support pedestal that allows for heating and cooling of a substrate disposed on the substrate support pedestal and independent temperature control of an inner zone and an outer zone of the substrate support pedestal.

### Description of the Related Art

Integrated circuits are fabricated by processes which produce intricately patterned material layers on substrate surfaces. Surfaces of substrates, e.g., crystalline silicon and epitaxial silicon layers, may be oxidized and/or susceptible to foreign contaminations, e.g. carbon or oxygen present during fabrication processes, which may directly impact the final product. Thus, substrate surfaces are routinely pre-cleaned before the fabrication processes.

Conventionally, pre-cleaning processes are performed in a vacuum processing chamber having a substrate support pedestal, on which a substrate is disposed. Temperature fluctuations may occur across the substrate surface. For example, an edge of the substrate support pedestal may have higher temperature than a center of the substrate support pedestal due to heated chamber walls of the vacuum processing chamber, causing an edge of the substrate to be rolled off. These temperature fluctuations may affect fabrication processes performed on or to the substrate, which may often reduce the uniformity of deposited films or etched structures along the substrate. Depending on the degree of variation along the surface of the substrate, device failure may occur due to the inconsistencies produced by the applications.

Substrate support pedestals sometimes have different zones with independent temperature control in order to create a more uniform temperature across the substrate. However, conventional fluid circuits used to control the temperature of the different zones use multiple fluid sources and heaters for each different zone which increases the size, cost, and maintenance of the pre-cleaning process.

Therefore, there is a need in the art for an improved fluid circuit for a substrate support pedestal for use in a pre-cleaning chamber.

### SUMMARY

In one embodiment, a fluid circuit for a substrate support assembly includes a substrate support. The substrate support includes an inner zone and an outer zone. The inner zone includes one or more inner channels and the outer zone includes one or more outer channels. The fluid circuit further includes, a first cooling channel fluidly coupled to the inner zone and a second cooling channel fluidly coupled to the outer zone. The fluid circuit further includes, a heater and one or more valves operable to switch between a first state and a second state. In the first state, the one or more valves fluidly couple the first cooling channel to the heater. In the second state, the one or more valves fluidly couple the second cooling channel to the heater.

In one embodiment, a processing chamber includes a chamber body at least partially defining an internal volume, a fluid chiller, and a substrate support including an inner zone and an outer zone. The inner zone includes one or more inner channels and the outer zone includes one or more outer channels. The processing chamber further includes a fluid circuit. The fluid circuit includes a first cooling channel fluidly coupled to the inner zone and a second cooling channel fluidly coupled to the outer zone. The fluid circuit further includes a heater and one or more valves operable to switch between a first state and a second state. In the first state, the one or more valves fluidly couple the first cooling channel to the heater. In the second state, the one or more valves fluidly couple the second cooling channel to the heater.

In one embodiment, a method of controlling a temperature of a substrate support pedestal includes measuring the temperature of the substrate support pedestal. The substrate support pedestal includes an inner zone having one or more inner channels and an outer zone having one or more outer channels. A first cooling channel is fluidly coupled to the inner zone and a second cooling channel is fluidly coupled to the outer zone. The method further includes flowing a first fluid through a heater and into the first cooling channel via one or more valves, the one or more valves being in a first state. The method further includes, switching the one or more valves from the first state to a second state and flowing a second fluid through the heater and into the second cooling channel via the one or more valves while the one or more valves are in the second state.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a cross sectional view of a processing chamber that is adapted to remove contaminants, such as oxides, from a surface of a substrate, according to one or more embodiments.

FIG. 2 depicts a cross sectional top view of the pedestal, according to one or more embodiments.

FIG. 3A depicts a schematic side view of the fluid circuit with a four valve configuration in a first state S1, according to one or more embodiments.

FIG. 3B depicts a schematic side view of the fluid circuit with a four valve configuration in a second state, according to one or more embodiments.

FIG. 3C depicts a schematic side view of the fluid circuit with a two valve configuration in a first state, according to one or more embodiments.

FIG. 3D depicts a schematic side view of the fluid circuit with a two valve configuration in a second state, according to one or more embodiments.

FIG. 4A depicts a schematic side view of a fluid circuit in a first state, according to one or more embodiments.

FIG. 4B depicts a schematic side view of the fluid circuit in a second state, according to one or more embodiments.

FIGS. 5A and 5B show a schematic cross-sectional side view of the four-way valve shown in FIGS. 4A and 4B, according to one or more embodiments.

FIG. 6 shows an operational flow chart for a method of controlling the temperature of a substrate support pedestal, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally relate to fluid circuit for the use in a pre-cleaning chamber, and more specifically, a fluid circuit used for controlling the temperature of a substrate support pedestal that allows for heating and cooling of a substrate disposed on the substrate support pedestal and independent temperature control of an inner zone and an outer zone of the substrate support pedestal.

Substrate support pedestals are commonly formed of one or more metal plates and a ceramic coating formed on the top most metal plate. This configuration enables efficient heating and cooling of the substrate support pedestals while also reducing contamination of a substrate disposed on the substrate support pedestal due to the ceramic coating. A substrate support pedestal may further include heating and cooling channels that are independently temperature-controlled for both an inner zone and an outer zone of the substrate support pedestal. Thus, a substrate residing on the substrate support pedestal can be maintained at a desired temperature profile (e.g., a uniform or offset temperature profile) across the entire surface.

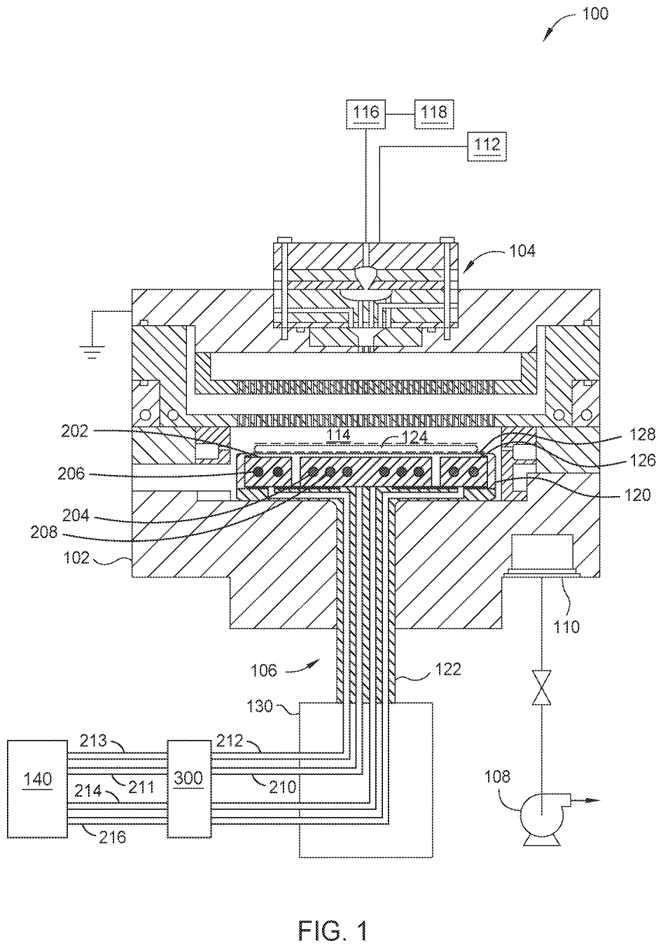

FIG. 1 is a cross sectional view of a processing chamber 100 that is adapted to remove contaminants, such as oxides, from a surface of a substrate. In some embodiments the processing chamber 100 is a plasma oxidation removal chamber. The processing chamber 100 may be particularly useful for performing a thermal or plasma-based cleaning process and/or a plasma assisted dry etch process. The processing chamber 100 includes a chamber body 102, a lid assembly 104, and a substrate support assembly 106. The lid assembly 104 is disposed at an upper end of the chamber body 102, and the substrate support assembly 106 is at least partially disposed within the chamber body 102. A vacuum system including a vacuum pump 108 and a vacuum port 110 can be used to remove gases from processing chamber 100. The vacuum port 110 is disposed in the chamber body 102, and the vacuum pump 108 is coupled to the vacuum port 110.

The processing chamber 100 also includes the controller 112 for controlling processes within the processing chamber 100. The controller 112 may include a central processing unit (CPU), memory, and support circuits (or I/O). The CPU may be one of any form of computer processors that are used in industrial settings for controlling various processes and hardware (e.g., pattern generators, motors, and other hardware) and monitor the processes (e.g., processing time and substrate position or location). The CPU may include a real-time proportional-integral-derivative (PID) controller that controls a solid-state relay (SSR) drive to supply power to inline heaters for inner and outer fluid channels, and may constantly monitor and maintain temperatures of an inner zone and an outer zone of substrate support assembly 106. The memory is connected to the CPU, and may include one or more of a readily available memory, such as random access memory (RAM), read only memory (ROM), floppy disk, hard disk, or any other form of digital storage, local or remote. Software instructions, algorithms and data can be coded and stored within the memory for instructing the CPU. The support circuits (not shown) are also connected to the CPU for supporting the processor in a conventional manner. The support circuits may include conventional cache, power supplies, clock circuits, input/output circuitry, subsystems, and the like. A program (or computer instructions) readable by the controller determines which tasks are performable on a substrate. The program may be software readable by the controller and may include code to monitor and control, for example, the processing time and substrate position or location. The program includes software to run communication and controls of the PID controller and the SSR drive.

The lid assembly 104 includes a plurality of stacked components bonded, welded, fused, or otherwise coupled with each other and configured to provide precursor gases and/or a plasma to a processing region 114 within the processing chamber 100. The lid assembly 104 may be connected to a remote plasma source 116 to generate plasma-byproducts that then pass through the remainder of the lid assembly 104. The remote plasma source 116 is coupled to a gas source 118 (or the gas source 118 is coupled directly to the lid assembly 104 in the absence of the remote plasma source 116). The gas source 118 may include helium, argon, or other inert gas that is energized into a plasma that is provided to the lid assembly 104. In some embodiments, the gas source 118 may include process gases to be activated for reaction with a substrate in the processing chamber 100.

The substrate support assembly 106 includes a substrate support pedestal 120 (also referred to as “dual-zone fast response pedestal” or simply as “pedestal” hereinafter) and a shaft 122 coupled to the pedestal 120. During processing, a substrate 124 may be disposed on a top surface 126 of the pedestal 120 of the substrate support assembly 106. In some embodiments, the top surface 126 of the pedestal 120 is covered with a ceramic coating 128 to prevent metal contamination of the substrate 124. Suitable ceramic coatings include, for example, aluminum oxide, aluminum nitride, silica, silicon, yttria, YAG, or other non-metallic coating materials. In various embodiments, the coating 128 can have a thickness in the range of 50 microns to 1000 microns. In some embodiments, the substrate 124 is configured to be vacuum chucked against the ceramic coating 128 disposed on the top surface 126 during processing. The pedestal 120 includes an outer zone 202 and an inner zone 204. The inner zone 204 includes one or more inner channels 208. The outer zone 202 includes one or more outer channels 206. The one or more inner channels 208 and the one or more outer channels 206 are configured to contain a cooling fluid to control the temperature of the inner zone 204 and the outer zone 202 of the pedestal 120.

The pedestal 120 is coupled to an actuator 130 by the shaft 122, which extends through a centrally-located opening formed in a bottom of the chamber body 102. The actuator 130 may be flexibly sealed to the chamber body 102 by bellows (not shown) that prevent vacuum leakage around the shaft 122. The actuator 130 allows the pedestal 120 to be moved vertically within the chamber body 102 between one or more processing positions, and a release or transfer position. The transfer position is slightly below the opening of a slit valve formed in a sidewall of the chamber body 102 to allow the substrate 124 to be robotically transferred into and out of the processing chamber 100. In some embodiments the shaft 122 is hollow.

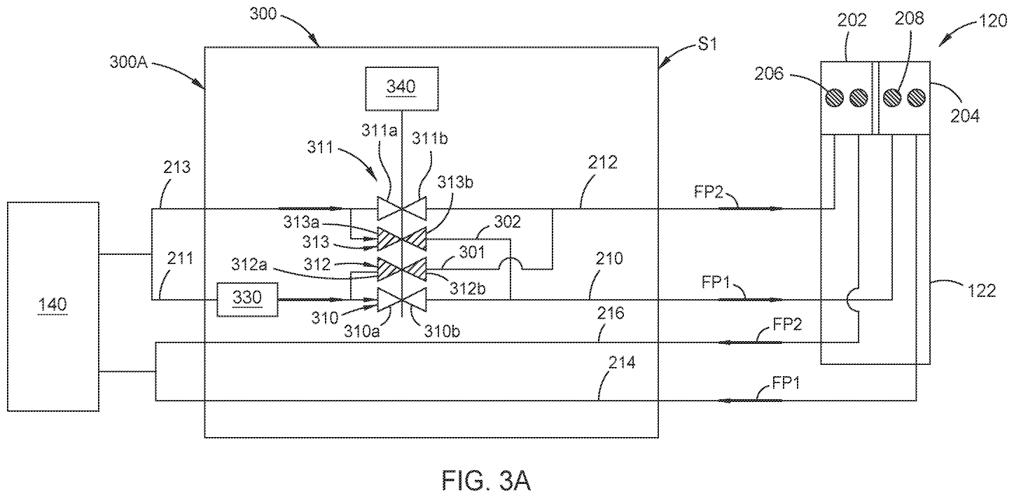

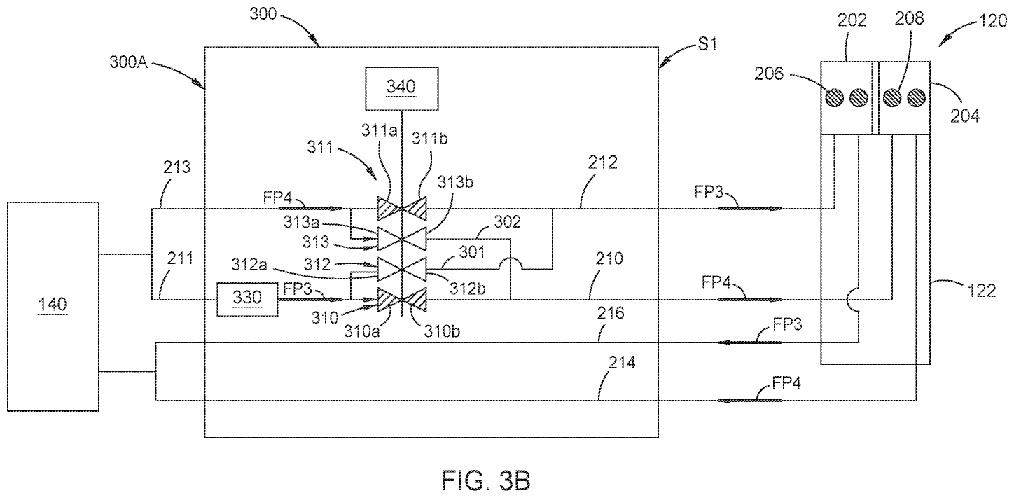

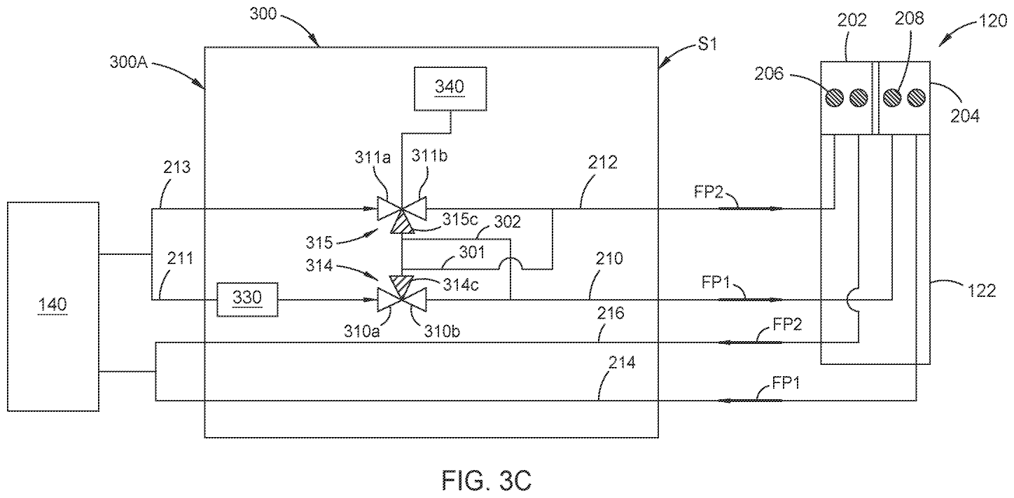

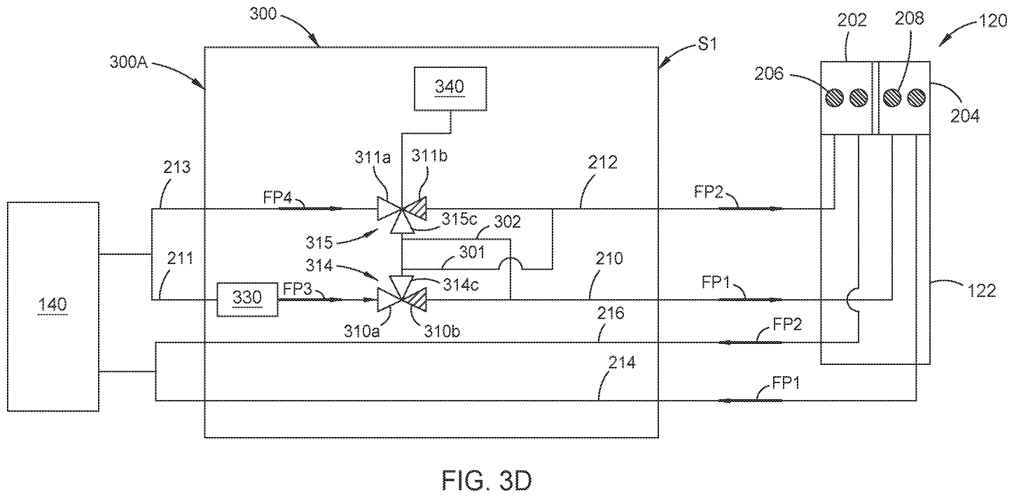

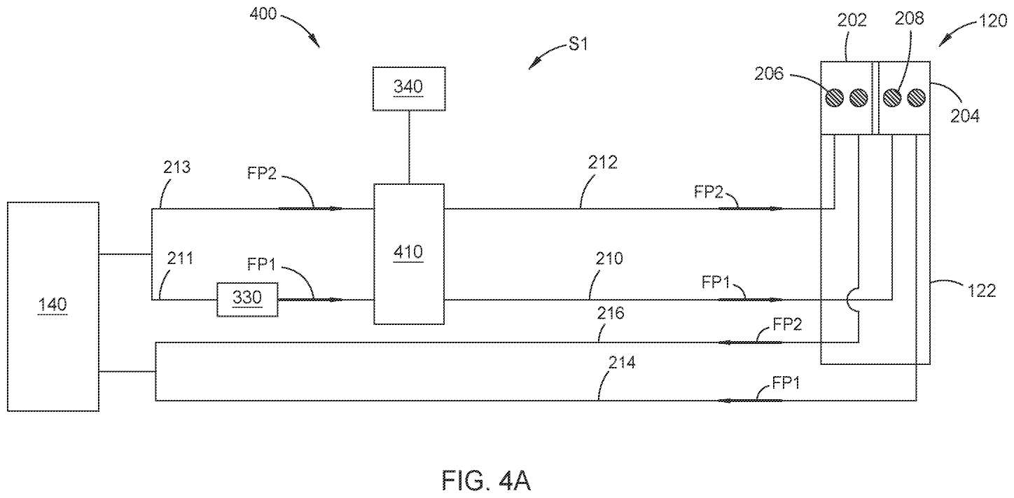

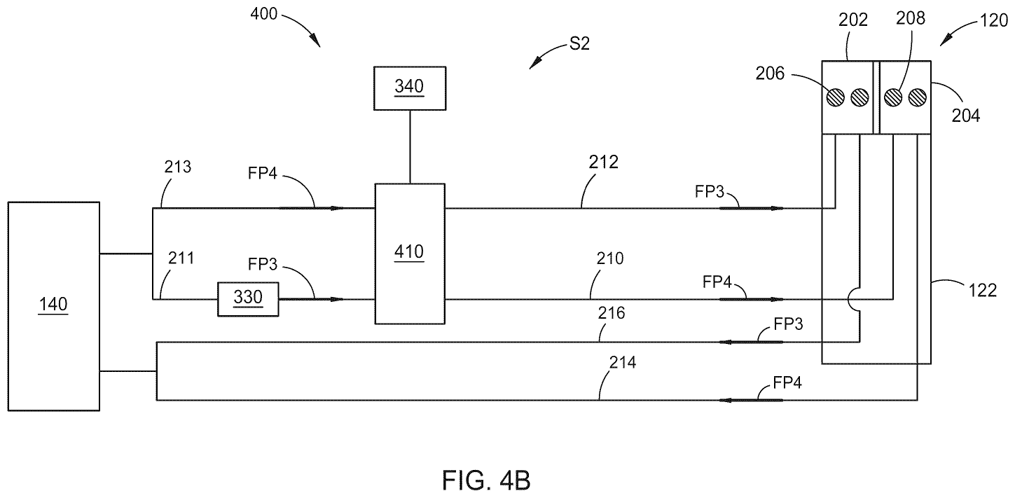

In some embodiments, a fluid chiller 140 is fluidly coupled to the processing chamber 100. In some embodiments, the fluid chiller 140 is disposed outside of the processing chamber. The fluid chiller 140 is positioned upstream of a fluid circuit 300. In some embodiments, the fluid chiller 140 is disposed inside an internal volume of the processing chamber 100. The fluid chiller 140 is configured to be fluidly coupled to the pedestal 120. In some embodiments, the fluid chiller 140 is a chiller. A first inlet channel 211 and a second inlet channel 213 are configured to fluidly couple to the fluid chiller 140. The first inlet channel 211 and the second inlet channel 213 connect to the fluid circuit 300. It should be understood that the fluid circuit 300 is shown schematically for illustrative purposes. More detailed embodiments of the fluid circuit 300 are described below in conjunction with FIGS. 3A-4B.

A first cooling channel 210 and a second cooling channel 212 extend from the fluid circuit 300 to the shaft 122. The first cooling channel 210 and the second cooling channel 212 fluidly connect the fluid chiller 140 to the pedestal 120. In some embodiments, the first cooling channel 210 fluidly couples to the one or more inner channels 208 in the inner zone 204 of the pedestal 120. In some embodiments, the second cooling channel 212 fluidly couples to the one or more outer channels 206 in the outer zone 202 of the pedestal 120. A first return channel 214 is fluidly coupled to the one or more inner channels 208, and a second return channel 216 is fluidly coupled to the one or more outer channels 206. The first return channel 214 and the second return channel 216 extend through the shaft 122 and connect to the fluid chiller 140.

In some process operations, the substrate 124 may be spaced from the top surface 126 by lift pins to perform additional thermal processing operations, such as performing an annealing step. The substrate 124 may be lowered to be placed directly in contact with the pedestal 120 to promote cooling of the substrate 124.

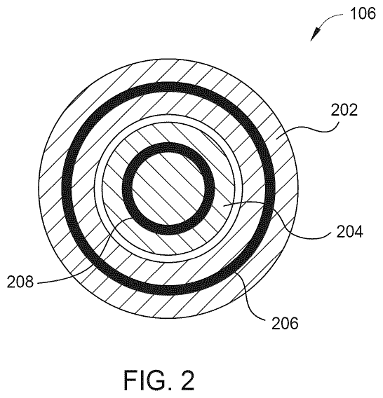

FIG. 2 depicts a cross sectional top view of the pedestal 120, according to one or more embodiments. In some embodiments the one or more outer channels 206 and the one or more inner channels 208 include a series of rings formed inside the inner zone 204 and the outer zone 202 of the pedestal. The one or more outer channels 206 and the one or more inner channels 208 are shown as rings for illustrative purposes. However, in various embodiments, the one or more outer channels 206 and the one or more inner channels 208 can have any geometry, such as a single ring, a single spiral, multiple spirals, etc.

FIG. 3A depicts a schematic side view of the fluid circuit 300 with a four valve configuration 300A in a first state S1, according to one or more embodiments. The fluid circuit 300 includes one or more valves operable to switch between a first state S1 (shown in FIG. 3A) and a second state S2 (shown in FIG. 3B). The fluid circuit 300 with a four valve configuration 300A includes the first inlet channel 211, the second inlet channel 213, the first cooling channel 210, the second cooling channel 212, a third cooling channel 301, a fourth cooling channel 302, and a heater 330. The fluid circuit 300 with a four valve configuration 300A further includes a first valve 310, a second valve 311, a third valve 312, and a fourth valve 313. In one or more embodiments, the first valve 310, the second valve 311, the third valve 312, and the fourth valve 313 are two-way valves. In one or more embodiments, the first valve 310, the second valve 311, the third valve 312, and the fourth valve 313 are in fluid communication with first cooling channel 210 and the second cooling channel 212.

The first valve 310 is fluidly coupled to the first cooling channel 210. The first valve 310 includes a first inlet 310a downstream and fluidly coupled to the heater 330 and a first outlet 310b fluidly coupled to the first cooling channel 210. The second valve 311 is fluidly coupled to the second cooling channel 212. The second valve 311 includes a second inlet 311a fluidly coupled to the fluid chiller 140 and a second outlet 311b fluidly coupled to the second cooling channel 212. The third valve 312 is fluidly coupled to the second cooling channel 212. The third valve 312 includes a third inlet fluidly 312a coupled to the heater 330 and a third outlet 312b fluidly coupled to the second cooling channel 212. The fourth valve 313 is fluidly coupled to the fourth cooling channel 302. The fourth valve 313 includes a fourth inlet fluidly 313a coupled to the fluid chiller 140 and a fourth outlet 313b fluidly coupled to the first cooling channel 210.

The heater 330 is coupled to the first cooling channel 210 via the first valve 310 and is coupled to the second cooling channel 212 via the third valve 312. In one or more embodiments the heater 330 is a resistive heater. In one or more embodiments, the heater 330 is connected to the controller 340. In one or more embodiments, the heater 330 is controlled by the controller 340.

In one or more embodiments, the fluid circuit 300 has two states. The first state S1 is shown in FIG. 3A. In the first state S1, the first cooling channel 210 is in fluid communication with the heater 330. The first state S1 includes a first flow path FP1 and a second flow path FP2. The first flow path FP1 includes the heater 330, the first cooling channel 210, the one or more inner channels 208, and the first return channel 214. The second flow path FP2 includes the second cooling channel 212, the one or more outer channels 206, and the second return channel 216. The first flow path FP1 and the second flow path FP2 are configured to receive a fluid.

In the first state S1, the first valve 310 and the second valve 311 are in the open position, and the third valve 312 and the fourth valve 313 are in the closed position, which creates the first flow path FP1 and the second flow path FP2. The first flow path FP1 is configured to flow a fluid from the fluid chiller 140 through the heater 330 and into the inner channels 208. In one or more embodiments, the first flow path FP1 is configured to allow for a fluid to flow from the fluid chiller 140 through the heater 330 and through the open first valve 310. The first flow path FP1 then continues down the first cooling channel 210 into the inner channels 208 in the inner zone 204. The first flow path FP1 continues from the inner zone 204 through the first return channel 214 back to the fluid chiller 140. The second path FP2 is configured to flow a fluid from the fluid chiller 140 and into the outer channels 206. In one or more embodiments, the second flow path FP2 is configured to allow for a fluid to flow from the fluid chiller 140 through the open second valve 311. The second flow path FP2 then continues down the second cooling channel 212 into the outer channels 206 in the outer zone 202. The second flow path FP2 continues from the outer zone 202 through the second return channel 216 back to the fluid chiller 140.

FIG. 3B depicts a schematic side view of the fluid circuit 300 with a four valve configuration 300A in a second state S2, according to one or more embodiments. In the second state S2, the second cooling channel 212 is in fluid communication with the heater 330. The second state S2 includes a third flow path FP3 and a fourth flow path FP4. The third flow path FP3 includes the heater 330, the second cooling channel 212, the one or more outer channels 206, and the second return channel 216. The fourth flow path FP4 includes the first cooling channel 210, the one or more inner channels 208, and the first return channel 214. The third flow path FP3 and the fourth flow path FP4 are configured to receive a fluid.

In the second state S2, the first valve 310 and the second valve 311 are in the closed position, and the third valve 312 and the fourth valve 313 are in the open position, which creates the third flow path FP3 and the fourth flow path FP4. The third flow path FP3 is configured to flow a fluid from the fluid chiller 140 through the heater 330 and into the outer channels 206. In one or more embodiments, the third flow path FP3 is configured to allow for a fluid to flow from the fluid chiller 140 through the heater 330 and through the open third valve 312. The third flow path FP3 then continues down the second cooling channel 212 into the outer channels 206 in the outer zone 202. The third flow path FP3 continues from the outer zone 202 through the second return channel 216 back to the fluid chiller 140. The fourth second path FP4 is configured to flow a fluid from the fluid chiller 140 and into the inner channels 208. In one or more embodiments, the fourth flow path FP4 is configured to allow for a fluid to flow from the fluid chiller 140 through the open fourth valve 313. The fourth flow path FP4 then continues down the first cooling channel 210 into the inner channels 208 in the inner zone 204. The fourth flow path FP4 continues from the inner zone 204 through the first return channel 214 back to the fluid chiller 140.

In one or more embodiments, the controller 340 is connected to the first valve 310, the second valve 311, the third valve 312, and the fourth valve 313. The controller 340 determines whether the first valve 310, the second valve 311, the third valve 312, and the fourth valve 313 are in the open position or the closed position. When a valve is in the open position, a fluid can pass through the valve. When a valve is in the closed position, the valve prevents the fluid from passing through. In one or more embodiments, the controller 340 controls the heater 330. In one or more embodiments, sensors, such as temperature sensor(s) and/or flow rate sensor(s), are disposed along the first cooling channel 210, the second cooling channel 212, a third cooling channel 301, a fourth cooling channel 302, the inner zone 204, the outer zone 202, the first return channel 214, and/or the second return channel 216. In one or more embodiments, the sensors help the controller 340 determine the current temperature of the inner zone 204 and the outer zone 202 and enable the controller 340 to adjust the power applied to the heater 330 (e.g., to control a temperature set point), as well as the position of the valves.

In one or more embodiments, the controller 340 can determine the current temperature of the inner zone 204 and the outer zone 202. A user can input a desired temperature of the inner zone 204 and the outer zone 202. The controller is configured to switch between the first state S1 and the second state S2 in order to adjust the temperature of the fluid flowing through the inner zone 204 and the outer zone 202. By switching between the first state S1 and the second state S2, the flow path of the first fluid F1 and the second fluid F2 can be adjusted to control the temperature of the inner zone 204 and the outer zone 202 of the pedestal 120.

FIG. 3C depicts a schematic side view of the fluid circuit 300 with a two valve configuration 300B in a first state S1, according to one or more embodiments. The fluid circuit 300 with a two valve configuration 300A includes a first three-way valve 314 and a second three-way valve 315. The first three-way valve 314 is fluidly coupled to the first cooling channel 210 and the second cooling channel 212. The first three-way valve 314 includes a first inlet fluidly 314a coupled to the heater 330, a first outlet 314b fluidly coupled to the first cooling channel 210, and a second outlet 314c fluidly coupled to the second cooling channel 212. The second three-way valve 315 is fluidly coupled to the first cooling channel 210 and the second cooling channel 212. The second three-way valve 315 includes a second inlet fluidly 315a coupled to the fluid chiller 140, a third outlet 315b fluidly coupled to the second cooling channel 212, and a fourth outlet 315c fluidly coupled to the first cooling channel 210.

In one or more embodiments, the two valve configuration 300B of the fluid circuit 300 has two states. The first state S1 is shown in FIG. 3C. In the first state S1, the first cooling channel 210 is in fluid communication with the heater 330. The first state S1 includes a first flow path FP1 and a second flow path FP2. The first flow path FP1 includes the heater 330, the first cooling channel 210, the one or more inner channels 208, and the first return channel 214. The second flow path FP2 includes the second cooling channel 212, the one or more outer channels 206, and the second return channel 216. The first flow path FP1 and the second flow path FP2 are configured to receive a fluid.

In the first state S1, the first outlet 314b and the third outlet 315b are in the open position and the second outlet 314c, and the fourth outlet 315c are in the closed position, which creates the first flow path FP1 and the second flow path FP2. The first flow path FP1 is configured to flow a fluid from the fluid chiller 140 through the heater 330 and into the inner channels 208. In one or more embodiments, the first flow path FP1 is configured to allow for a fluid to flow from the fluid chiller 140 through the heater 330 and through the open first outlet 314b. The first flow path FP1 then continues down the first cooling channel 210 into the inner channels 208 in the inner zone 204. The first flow path FP1 continues from the inner zone 204 through the first return channel 214 back to the fluid chiller 140. The second path FP2 is configured to flow a fluid from the fluid chiller 140 and into the outer channels 206. In one or more embodiments, the second flow path FP2 is configured to allow for a fluid to flow from the fluid chiller 140 through the open third outlet 315b. The second flow path FP2 then continues down the second cooling channel 212 into the outer channels 206 in the outer zone 202. The second flow path FP2 continues from the outer zone 202 through the second return channel 216 back to the fluid chiller 140.

FIG. 3D depicts a schematic side view of the fluid circuit 300 with a two valve configuration 300B in a second state S2, according to one or more embodiments. In the second state S2, the second cooling channel 212 is in fluid communication with the heater 330. The second state S2 includes a third flow path FP3 and a fourth flow path FP4. The third flow path FP3 includes the heater 330, the second cooling channel 212, the one or more outer channels 206, and the second return channel 216. The fourth flow path FP4 includes the first cooling channel 210, the one or more inner channels 208, and the first return channel 214. The third flow path FP3 and the fourth flow path FP4 are configured to receive a fluid.

In the second state S2, the first outlet 314b and the third outlet 315b are in the closed position and the second outlet 314c and the fourth outlet 315c are in the open position, which creates the third flow path FP3 and the fourth flow path FP4. The third flow path FP3 is configured to flow a fluid from the fluid chiller 140 through the heater 330 and into the outer channels 206. In one or more embodiments, the third flow path FP3 is configured to allow for a fluid to flow from the fluid chiller 140 through the heater 330 and through the open second outlet 314c. The third flow path FP3 then continues down the second cooling channel 212 into the outer channels 206 in the outer zone 202. The third flow path FP3 continues from the outer zone 202 through the second return channel 216 back to the fluid chiller 140. The fourth second path FP4 is configured to flow a fluid from the fluid chiller 140 and into the inner channels 208. In one or more embodiments, the fourth flow path FP4 is configured to allow for a fluid to flow from the fluid chiller 140 through the open fourth outlet 315c. The fourth flow path FP4 then continues down the first cooling channel 210 into the inner channels 208 in the inner zone 204. The fourth flow path FP4 continues from the inner zone 204 through the first return channel 214 back to the fluid chiller 140.

In one or more embodiments, the controller 340 is connected to the first three-way valve 314 and the second three-way valve 315. The controller 340 determines whether the two valve configuration 300B of the fluid circuit 300 is in the first state S1 or the second state S2. When a valve is in the open position, a fluid can pass through the valve. In one or more embodiments, the controller 340 controls the heater 330. In one or more embodiments, sensors such as temperature sensors and/or flow rate sensor are disposed along the first cooling channel 210, the second cooling channel 212, a third cooling channel 301, a fourth cooling channel 302, the inner zone 204, the outer zone 202, the first return channel 214, and/or the second return channel 216. In one or more embodiments, the sensors help the controller determine the current temperature of the inner zone 204 and the outer zone 202 and adjust the power applied to the heater 330, as well as the position of the valves.

In one or more embodiments, the controller 340 can determine the current temperature of the inner zone 204 and the outer zone 202. A user can input a desired temperature of the inner zone 204 and the outer zone 202. The controller can switch between the first state S1 and the second state S2 in order to adjust the temperature of the fluid flowing through the inner zone 204 and the outer zone 202. By switching between the first state S1 and the second state S2, the flow path of the first fluid F1 and the second fluid F2 can be adjusted to control the temperature of the inner zone 204 and the outer zone 202 of the pedestal 120.

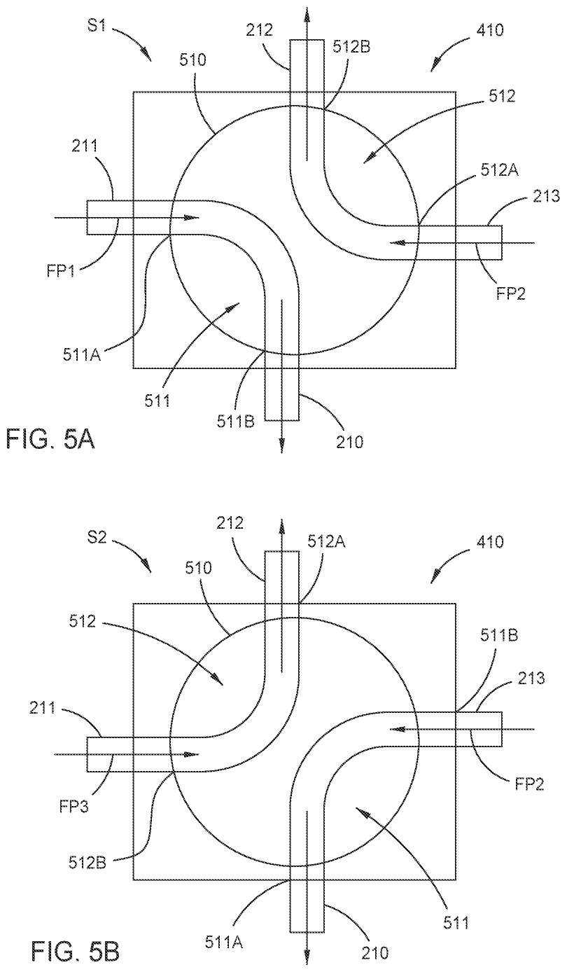

FIG. 4A depicts a schematic side view of the fluid circuit 400 in a first state S1, according to one or more embodiments. The fluid circuit 400 has one four-way valve 410 that is fluidly coupled to the first cooling channel 210 and the second cooling channel 212. It should be understood that the four-way valve 410 is shown schematically in FIGS. 4A and 4B for illustrative purposes. A more detailed depiction is shown in FIGS. 5A and 5B.

In one or more embodiments the fluid circuit 400 has two positions. The first state S1 is shown in FIG. 3C. In the first state S1, the first cooling channel 210 is in fluid communication with the heater 330. The first state S1 includes a first flow path FP1 and a second flow path FP2. The first flow path FP1 includes the heater 330, the first cooling channel 210, the one or more inner channels 208, and the first return channel 214. The second flow path FP2 includes the second cooling channel 212, the one or more outer channels 206, and the second return channel 216. The first flow path FP1 and the second flow path FP2 are configured to receive a fluid.

In the first state S1, the four-way valve 410 is in a first position, which creates the first flow path FP1 and the second flow path FP2. The first flow path FP1 is configured to flow a fluid from the fluid chiller 140 through the heater 330 and into the inner channels 208. In one or more embodiments, the first flow path FP1 is configured to allow for a fluid to flow from the fluid chiller 140 through the heater 330 and through the four-way valve 410. The first flow path FP1 then continues down the first cooling channel 210 into the inner channels 208 in the inner zone 204. The first flow path FP1 continues from the inner zone 204 through the first return channel 214 back to the fluid chiller 140. The second path FP2 is configured to flow a fluid from the fluid chiller 140 and into the outer channels 206. In one or more embodiments, the second flow path FP2 is configured to allow for a fluid to flow from the fluid chiller 140 through the open second valve 311. The second flow path FP2 then continues down the second cooling channel 212 into the outer channels 206 in the outer zone 202. The second flow path FP2 continues from the outer zone 202 through the second return channel 216 back to the fluid chiller 140.

FIG. 4B depicts a schematic side view of the fluid circuit 400 in a second state S2, according to one or more embodiments. In the second state S2, the second cooling channel 212 is in fluid communication with the heater 330. The second state S2 includes a third flow path FP3 and a fourth flow path FP4. The third flow path FP3 includes the heater 330, the second cooling channel 212, the one or more outer channels 206, and the second return channel 216. The fourth flow path FP4 includes the first cooling channel 210, the one or more inner channels 208, and the first return channel 214. The third flow path FP3 and the fourth flow path FP4 are configured to receive a fluid.

In the second state S2, the four-way valve 410 is in a second position, which creates the third flow path FP3 and the fourth flow path FP4. The third flow path FP3 is configured to flow a fluid from the fluid chiller 140 through the heater 330 and into the outer channels 206. In one or more embodiments, the third flow path FP3 is configured to allow for a fluid to flow from the fluid chiller 140 through the heater 330 and through the four-way valve 410. The third flow path FP3 then continues down the second cooling channel 212 into the outer channels 206 in the outer zone 202. The third flow path FP3 continues from the outer zone 202 through the second return channel 216 back to the fluid chiller 140. The fourth second path FP4 is configured to flow a fluid from the fluid chiller 140 and into the inner channels 208. In one or more embodiments, the fourth flow path FP4 is configured to allow for a fluid to flow from the fluid chiller 140 through the four-way valve 410. The fourth flow path FP4 then continues down the first cooling channel 210 into the inner channels 208 in the inner zone 204. The fourth flow path FP4 continues from the inner zone 204 through the first return channel 214 back to the fluid chiller 140.

In one or more embodiments, the controller 340 is connected to the four-way valve 410. The controller 340 determines whether the fluid circuit 400 is in the first state S1 or the second state S2. In one or more embodiments, the controller 340 controls the heater 330. In one or more embodiments, sensors such as temperature sensors and/or flow rate sensor are disposed along the first cooling channel 210, the second cooling channel 212, the inner zone 204, the outer zone 202, the first return channel 214, and/or the second return channel 216. In one or more embodiments, the sensors help the controller determine the current temperature of the inner zone 204 and the outer zone 202 and adjust the intensity of the heater 330, as well as the position of the valve.

In one or more embodiments, the controller 340 can determine the current temperature of the inner zone 204 and the outer zone 202. A user can input a desired temperature of the inner zone 204 and the outer zone 202. The controller can switch between the first state S1 and the second state S2 in order to adjust the temperature of the fluid flowing through the inner zone 204 and the outer zone 202. By switching between the first state S1 and the second state S2 the flow path of the first fluid F1 and the second fluid F2 can be adjusted to control the temperature of the inner zone 204 and the outer zone 202 of the pedestal 120.

FIGS. 5A and 5B show schematic cross-sectional side views of the four-way valve 410 shown in FIGS. 4A and 4B. FIG. 5A shows the four-way valve 410 in the first state S1 of the fluid circuit 400, as shown in FIG. 4A. The four-way valve 410 includes a moveable section 510. The moveable section 510 includes a first valve channel 511 and a second valve channel 512. The first valve channel 511 comprises a first opening 511A and a second opening 511B. The second valve channel 512 comprises a third opening 512A and a fourth opening 512B. When the four-way valve 410 is in the first state S1 the first opening 511A is fluidly coupled to the first inlet channel 211. In the first state S1, the first opening 511A serves as an inlet for the first valve channel 511. In the first state S1, the second opening 511B is fluidly coupled to the first cooling channel 210. In the first state S1, the second opening 511B serves as an outlet for the first valve channel 511. In the first state S1 the first flow path FP1 will flow through the first valve channel 511, and continue into the first cooling channel 210. When the four-way valve is in the first state S1, the third opening 512A is fluidly coupled to the second inlet channel 213. In the first state S1, the third opening 512A serves as an inlet for the second valve channel 512. In the first state S1, the fourth opening 512B is fluidly coupled to the second cooling channel 212. In the first state S1, the fourth opening 512B serves as an outlet for the second valve channel 512. In the first state S1, the second flow path FP2 will flow through the second valve channel 512, and continue into the second cooling channel 212.

FIG. 5B shows the four-way valve 410 in the second state S2 of the fluid circuit 400, as shown in FIG. 4B. In the second state S2, the moveable section 510 of the four-way valve 410 is adjusted to create the third flow path FP3 and the fourth flow path FP4. When the four-way valve 410 is in the second state S2, the fourth opening 512B is fluidly coupled to the first inlet channel 211. In the second state S2, the fourth opening 512B serves as an inlet for the second valve channel 512. In the second state S2, the third opening 512A is fluidly coupled to the second cooling channel 212. In the second state S2, the third opening 512A serves as an outlet for the second valve channel 512. In the second state S2 the third flow path FP3 will flow through the second valve channel 512, and continue into the second cooling channel 212. When the four-way valve is in the second state S2, the second opening 511B is fluidly coupled to the second inlet channel 213. In the second state S2, the second opening 511B serves as an inlet for the first valve channel 511. In the second state S2, the first opening 511A is fluidly coupled to the first cooling channel 210. In the second state S2, the first opening 511A serves as an outlet for the first valve channel 511. In the second state S2, the fourth flow path FP4 will flow through the first valve channel 511, and continue into the first cooling channel 210.

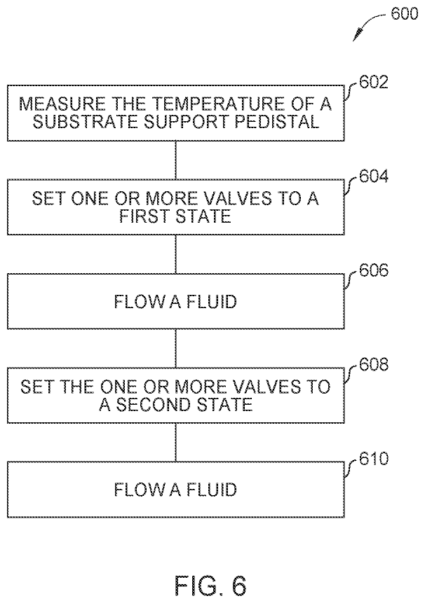

FIG. 6 shows an operational flow chart for a method 600 of controlling the temperature of a substrate support pedestal, according to one or more embodiments.

At operation 602, a temperature of the substrate support pedestal is measured. In one or more embodiments, the substrate support pedestal includes an inner zone with one or more inner channels and an outer zone with one or more outer channels. In some embodiments, operation 602 is performed with the substrate support pedestal 120 described herein. In some embodiments the temperature is measured with a temperature sensor connected to a controller.

At operation 604, one or more valves are set to a first state. The first state includes a first flow path and a second flow path. In some embodiments, a controller sets the one or more valves to the first state. In some embodiments, the first flow path includes a heater, a first cooling channel, the one or more inner channels, and a first return channel. In some embodiments, the second flow path includes a second cooling channel, the one or more outer channels, and a second return channel. In some embodiments, operation 604 is performed using the controller 340, the fluid circuit 300 with the four valve configuration 300A, the fluid circuit 300 with the two valve configuration 300B, the fluid circuit 400, the first flow path FP1, the second flow path FP2, and/or any combination of the components described herein.

At operation 606, a fluid is flowed through the first flow path and the second flow path. In some embodiments, operation 606 is performed after operation 604. In some embodiments, operation 606 is performed using the first fluid F1, the second fluid F2, and/or any combination of the components described herein.

At operation 608, one or more valves are set to a second state. The second state includes a third flow path and a fourth flow path. In some embodiments, a controller sets the one or more valves to the second state. In some embodiments, the third flow path includes a heater, a second cooling channel, the one or more outer channels, and a second return channel. In some embodiments, the fourth flow path includes a first cooling channel, the one or more inner channels, and a first return channel. In some embodiments, operation 608 is performed using the controller 340, the fluid circuit 300 with the four valve configuration 300A, the fluid circuit 300 with the two valve configuration 300B, the fluid circuit 400, the third flow path FP3, the fourth flow path FP4, and/or any combination of the components described herein.

At operation 610, a fluid is flowed through the third flow path and the fourth flow path. In some embodiments, operation 610 is performed after operation 608. In some embodiments, operation 610 is performed using the first fluid F1, the second fluid F2, and/or any combination of the components described herein.

In some embodiments the method 600 further comprises measuring the temperature of the inner zone and the outer zone of the pedestal. In some embodiments, the method 600 further comprises adjusting the position of the flow circuit. In some embodiments, operations 606-612 are repeated until the inner zone and the outer zone reach a desired temperature.

Benefits of the present disclosure include enhanced temperature control, decreased maintenance, decreased number of parts, decreased costs, decreased apparatus size, and increased throughput and efficiency.

It is contemplated that one or more aspects disclosed herein may be combined. As an example, one or more aspects, features, components, operations and/or properties of the processing chamber 100, the fluid chiller 140, the pedestal 120, the shaft 122, the first cooling channel 210, the second cooling channel 212, the first return channel 214, the second return channel 216, the inner zone 204, the outer zone 202, the one or more inner channels 208, the one or more outer channels 206, the fluid circuit 300, the four valve configuration 300A, the first valve 310, the second valve 311, the third valve 312, the fourth valve 313, the heater 330, the controller 340, the third cooling channel 301, the fourth cooling channel 302, the two valve configuration 300B, the first three-way valve 314, the second three-way valve 315, the fluid circuit 400, the four-way valve 410, and/or the method 600 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate support assembly comprising:
a substrate support comprising an inner zone and an outer zone, wherein the inner zone comprises one or more inner channels, and the outer zone comprises one or more outer channels;
a fluid circuit comprising:
a first cooling channel fluidly coupled to the inner zone;
a second cooling channel fluidly coupled to the outer zone;
a heater; and
one or more valves operable to switch between a first state and a second state, wherein:
in the first state, the one or more valves fluidly couple the first cooling channel to the heater, and
in the second state, the one or more valves fluidly couple the second cooling channel to the heater.

2. The substrate support assembly of claim 1, wherein the fluid circuit further comprises:
a first return channel in fluid communication with the inner zone; and
a second return channel in fluid communication with the outer zone.

3. The substrate support assembly of claim 2, wherein, when the one or more valves are in the first state, a first flow path and a second flow path are formed, wherein:
the first flow path comprises:
the heater;
the first cooling channel;
the one or more inner channels; and
the first return channel; and
the second flow path comprises:
the second cooling channel;
the one or more outer channels; and
the second return channel.

4. The substrate support assembly of claim 3, wherein, when the one or more valves are in the second state, a third flow path and a fourth flow path are formed, wherein:
the third flow path comprises:
the heater;
the second cooling channel;
the one or more outer channels; and
the second return channel; and
the fourth flow path comprises:
the first cooling channel;
the one or more inner channels; and
the first return channel.

5. The substrate support assembly of claim 1, further comprising a fluid chiller positioned upstream of the heater and the one or more valves, the fluid chiller being in fluid communication with the first cooling channel and the second cooling channel.

6. The substrate support assembly of claim 1, wherein the one or more valves comprises a four-way valve in fluid communication with the first cooling channel and the second cooling channel.

7. The substrate support assembly of claim 1, wherein the one or more valves comprises:
a first three way valve positioned downstream of the heater, the first three way valve being in fluid communication with the first cooling channel when the one or more valves are in the first state, and the first three way valve being in fluid communication with the second cooling channel when the one or more valves are in the second state; and
a second three way valve, the second three way valve being in fluid communication with the second cooling channel when the one or more valves are in the first state, and the second three way valve being in fluid communication with the first cooling channel when the one or more valves are in the second state.

8. The substrate support assembly of claim 1, wherein the one or more valves comprises:
a first valve positioned downstream of the heater, the first valve being in fluid communication with the first cooling channel;
a second valve, the second valve being in fluid communication with the second cooling channel;
a third valve positioned downstream of the heater, the third valve being in fluid communication with the second cooling channel; and
a fourth valve, the fourth valve being in fluid communication with the first cooling channel.

9. The substrate support assembly of claim 1, further comprising a controller configured to switch the one or more valves between the first state and the second state.

10. A processing chamber comprising:
a chamber body at least partially defining an internal volume;
a fluid chiller;
a substrate support comprising an inner zone and an outer zone, wherein the inner zone comprises one or more inner channels, and the outer zone comprises one or more outer channels;
a fluid circuit comprising:
a first cooling channel fluidly coupled to the inner zone;
a second cooling channel fluidly coupled to the outer zone;
a heater; and
one or more valves in fluid communication with the fluid chiller and operable to switch between a first state and a second state, wherein:
in the first state, the one or more valves fluidly couple the first cooling channel to the heater, and
in the second state, the one or more valves fluidly couple the second cooling channel to the heater.

11. The processing chamber of claim 10, wherein the fluid circuit further comprises:
a first return channel in fluid communication with the inner zone; and
a second return channel in fluid communication with the outer zone.

12. The processing chamber of claim 11, wherein, when the one or more valves are in the first state, a first flow path and a second flow path are formed, wherein:
the first flow path comprises:
the heater;
the first cooling channel;
the one or more inner channels; and
the first return channel; and
the second flow path comprises:
the second cooling channel;
the one or more outer channels; and
the second return channel.

13. The processing chamber of claim 11, when the one or more valves are in the second state, a third flow path and a fourth flow path are formed, wherein:
the third flow path comprises:
the heater;
the second cooling channel;
the one or more outer channels; and
the second return channel; and
the fourth flow path comprises:
the first cooling channel;
the one or more inner channels; and
the first return channel.

14. The processing chamber of claim 10, wherein the fluid chiller is positioned upstream of the heater and the one or more valves, the fluid chiller being in fluid communication with the first cooling channel and the second cooling channel.

15. The processing chamber of claim 10, wherein the one or more valves comprises a four-way valve in fluid communication with the first cooling channel and the second cooling channel.

16. The processing chamber of claim 10, wherein the one or more valves comprises:
a first three way valve positioned downstream of the heater, the first three way valve being in fluid communication with the first cooling channel when the one or more valves are in the first state, and the first three way valve being in fluid communication with the second cooling channel when the one or more valves are in the second state; and
a second three way valve, the second three way valve being in fluid communication with the second cooling channel when the one or more valves are in the first state, and the second three way valve being in fluid communication with the first cooling channel when the one or more valves are in the second state.

17. The processing chamber of claim 10, wherein the one or more valves comprises:
a first valve positioned downstream of the heater, the first valve being in fluid communication with the first cooling channel;
a second valve, the second valve being in fluid communication with the second cooling channel;
a third valve positioned downstream of the heater, the third valve being in fluid communication with the second cooling channel; and
a fourth valve, the fourth valve being in fluid communication with the first cooling channel.

18. The fluid circuit of claim 10, further comprising a controller configured to switch the one or more valves between the first state and the second state.

19. A method of controlling a temperature of a substrate support pedestal comprising:
measuring the temperature of the substrate support pedestal, wherein the substrate support pedestal comprises an inner zone having one or more inner channels and an outer zone having one or more outer channels, a first cooling channel being fluidly coupled to the inner zone, and a second cooling channel being fluidly coupled to the outer zone;
flowing a first fluid through a heater and into the first cooling channel via one or more valves, the one or more valves being in a first state;
switching the one or more valves from the first state to a second state; and
flowing a second fluid through the heater and into the second cooling channel via the one or more valves while the one or more valves are in the second state.

20. The method of claim 19, wherein when the one or more valves are in the first state, a first flow path and a second flow path are formed, and when the one or more valves are in the second state, a third flow path and a fourth flow path are formed, wherein:
the first flow path comprises the heater, the first cooling channel, the one or more inner channels, and a first return channel;
the second flow path comprises the second cooling channel, the one or more outer channels, and a second return channel;
the third flow path comprises the heater, the second cooling channel, the one or more outer channels, and the second return channel; and
the fourth flow path comprises the first cooling channel, the one or more inner channels, and the first return channel.
